(19) United States
(12) Patent Application Publication
(10) Pub. No.: US 2006/0065958 A1
(43) Pub. Date: Mar. 30, 2006

(54) Three dimensional package and packaging method for integrated circuits

(76) Inventors: Pei-Haw Tsao, Tai-chung (TW); Chao-Yuan Su, Koahsiung City (TW); Allan Lin, Hsinchu City (TW); Frank Wu, Koahsiung Hsien (TW); Chender Huang, Hsinchu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/953,045

(22) Filed: Sep. 29, 2004

(51) Int. Cl. H01L 23/495

(52) U.S. Cl. 257/678

(57) ABSTRACT

A 3D package has: a three-dimensional (3D) package substrate, a land grid array (LGA) or quad flat no-lead (QFN) package mounted on the 3D package substrate, the LGA or QFN package having an LGA or QFN die on a first side of an LGA or QFN package substrate, and a second die mounted directly on a second side of the LGA or QFN package substrate opposite the first side.

### FIELD OF THE INVENTION

The present invention relates to packaging of integrated circuits generally, and more specifically to three dimensional (3D) packages.

### BACKGROUND

The need for increased memory capacity with a smaller footprint has led to development of 3D packages and packaging techniques. 3D packages generally allow smaller, thinner packages. For many years, new package form factors have allowed size reduction in both the length and width (X and Y dimensions) of packages. More recently, there has been an increased interest in reducing the height (Z dimension). Increased use of portable devices, such as the exponential grown in wireless communications has increased the need for even more dramatic height (Z dimension) reduction. To meet these challenges, 3D packaging has been achieved, typically by stacking two or more die within a single package.

3D packages allow more semiconductor functions per unit of area of board space and more semiconductor functions per unit of volume of application space, as well as significant size and weight reductions. Including two or more die in one package decreases the number of components mounted on a given printed circuit board. 3D packages provide a single package for assembly, test and handling which reduces package cost.

3D packages also allow a low overall cost without requiring cutting edge technology, because a desired set of functions can be included within the 3D package without having to put all of the functions in a single IC chip. Also, because die to die interconnects can be made within the package, the package I/O and the printed circuit board (PCB) routing are simplified. Because multiple dies are included with the footprint of a single 3D package, the length and/or width of the PCB can be reduced.

FIG. 1 shows an example of a conventional 3D package 100. The package of FIG. 1 has a plastic ball grid array (PBGA) package 101, with a land grid array (LGA) package 111 mounted thereon. A PBGA package 101 is a well known structure in which an integrated circuit (IC) die 104 is die bonded to the top side of the package substrate 102 using die attach adhesive (not shown). The die 104 is then wire bonded using gold wires 106, 109 to wire bond pads (not shown) on the package substrate 102. Traces (not shown) from the wire bond pads take the signals to vias in substrate 102, which carry them to the bottom side of the substrate and then to circular solder pads. The bottom side solder pads are laid out on a square or rectangular grid, to which solder balls 107 are attached. An overmold 110 (or possibly a liquid or “glob-top” encapsulation) is then performed to completely encapsulate the die 104, wires 106 and 109 and substrate wire bond pads.

An LGA chip scale package (CSP) 111 is a package without any terminations (solder balls) on the bottom. Instead, the LGA package 111 has tiny round gold plated pads on the bottom (top surface in the orientation of FIG. 1), similar to a ball grid array (BGA) package without BGA balls soldered to each pad. The LGA package 111 includes an LGA package substrate 112, and a die 114 wire bonded to the substrate 112 using wires 116. An overmold or encapsulant 120 encapsulates the die 114 and wires 116.

In the prior art 3D package 100 of FIG. 1, the PBGA package 101 and LGA package 111 are formed separately. The LGA package 111 is stacked on top of the PBGA package 101 with the encapsulant 120 of LGA package 111 facing the encapsulant 110 of PBGA package 101. The two encapsulant layers 110 and 120 may be bonded using a thin layer of the same molding compound as the encapsulant layers, or a suitable adhesive. The pads (not shown) of the LGA package 111 are then wire bonded by wires 122 to the package substrate 102 of the 3D package. Then a third layer of encapsulant or molding compound 130 is applied, to encapsulate the PBGA package 101, LGA package 111, and wires 122.

The above described method requires three separate molding processes, for molding compounds 110, 120 and 130. This increases the cost and fabrication time of the 3D package 100. Further the thickness of the 3D package 100 is driven by the need for three layers of encapsulant 110, 120 and 130, respectively covering the die 104, die 114, and the packages 101 and 111.

An improved package and packaging method are desired.

### SUMMARY OF THE INVENTION

A packaging method comprises the steps of: mounting on a three-dimensional (3D) package substrate a land grid array (LGA) or quad flat no-lead (QFN) package having an LGA or QFN die on a first side of an LGA or QFN package substrate, respectively, and mounting a second die directly on a second side of the LGA or QFN package substrate opposite the first side thereof.

A 3D package comprises: a three-dimensional (3D) package substrate, a land grid array (LGA) or quad flat no-lead (QFN) package mounted on the 3D package substrate, the LGA or QFN package having an LGA or QFN die on a first side of an LGA or QFN package substrate, and a second die mounted directly on a second side of the LGA or QFN package substrate opposite the first side thereof.

### BRIEF DESCRIPTION OF THE DRAWINGS

FIG. 1 is a cross sectional view of a conventional 3D package.

FIG. 2 is a cross sectional view of a package according to an exemplary embodiment of the invention.

FIG. 3 is a cross sectional view of a package according to another exemplary embodiment of the invention, in which the die is flip chip mounted.

FIG. 4 is a cross sectional view of a package according to another exemplary embodiment of the invention, in which the LGA package includes a flip chip mounted die.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

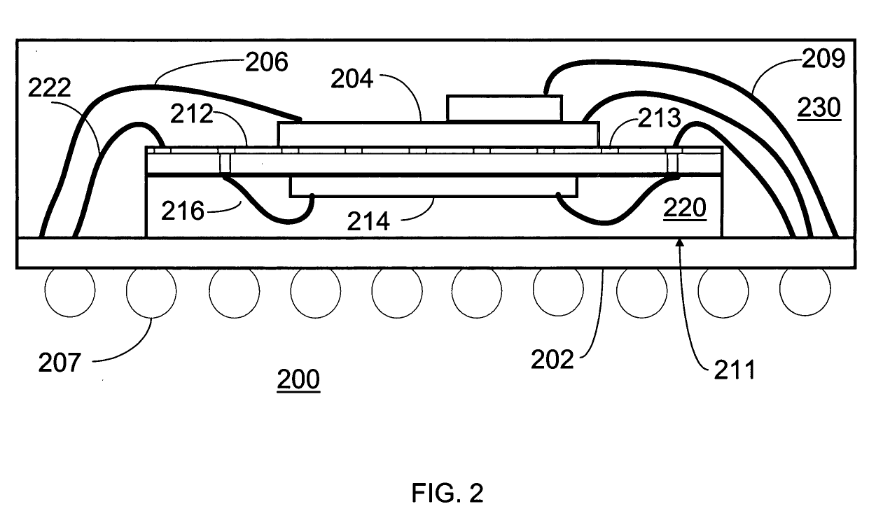

FIG. 2 is a side cross sectional view of an exemplary 3D package 200 according to one embodiment of the present invention. The 3D package 200 is formed by integrating the LGA CSP 211 into the final CSP assembly. In the 3D package 200 of FIG. 2, there is no separate PBGA package. Thus, the 3D package 200 can be fabricated with only two molding steps, instead of three. The first molding step encapsulates the LGA package 211, and the second molding step encapsulates the LGA package 211 and the second die 204 of the 3D package 200 in a single step.

An exemplary packaging method comprises the steps of: providing a land grid array (LGA) package 211 having an LGA die 214 on a first side of an LGA package substrate 212, orienting the LGA package 211 with the LGA package substrate 212 facing away from a 3D package substrate 202, mounting the LGA package 211 on the three-dimensional (3D) package substrate 202, and mounting a second die 204 directly on a second side of the LGA package substrate 212 opposite the first side thereof.

A plurality of lands 213 of the LGA package 211 are wire bonded to contacts on the 3D package substrate 202. A plurality of contacts of the second die 204 are wire bonded to contacts on the 3D package substrate 202. A plurality of solder balls 207 are applied to pads on a side of the 3D package substrate 202 opposite the LGA package 211.

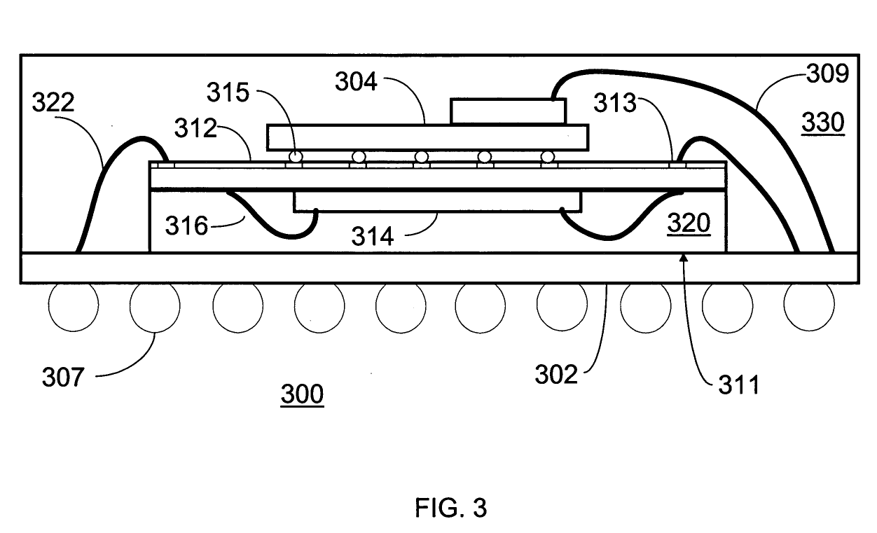

The LGA CSP 211 can be formed by any technique for fabricating an LGA package, including, but not limited to, conventional methods. The LGA package 211 includes an LGA package substrate 212. The LGA package substrate 212 has tiny round gold plated pads (lands) 213 on the bottom (top surface in FIG. 2). The substrate 212 may be a double-sided FR-4 or FR-5 (or the equivalent) printed wiring board with traces on the die side connected by way of vias to the land grid pad pattern 213 on the bottom side. The LGA die 214 is die bonded to the LGA package substrate 212 using an adhesive, such as an epoxy, for example, Ablestick Ablebond 8355F epoxy, by the National Starch and Chemical Co. of Rancho Dominguez, Calif. The pads of die 214 are wire bonded to corresponding lands 213 on the substrate 212 using wires 216. The LGA die can be flip-chip mounted to the LGA substrate 212 in other embodiments of the invention, as shown in FIG. 3, discussed further below.

The 3D package substrate 202 may be, for example The a double-sided FR-4 or FR-5 (or the equivalent) printed wiring board with traces on the die side connected by way of vias to the ball grid pad pattern 207 on the bottom side.

An overmold or encapsulant 220 encapsulates the die 214 and wires 216 to complete the LGA CSP 211. An exemplary molding compound is Plaskon SMT-B-1 Series made by the Libbey-Owens Ford Glass Co. of Toledo, Ohio, or Sumitomo EME-7372 made by Taiwan Sumitomo Bakelite Co. Ltd. of Ta Liao, Kaohsiung, Taiwan.

The complete LGA package 211 is flipped over, with the land grid 213 on top, as shown in FIG. 2, a 2100a adhesive nd the LGA package 211 is mounted on the 3D package substrate 202. Die attach adhesives such as Ablebond 2100A by Ablestick Laboratories, based in Rancho Dominguez, Calif. and QMI536 by Henkel Loctite Corp of Industry, Calif., are examples of a suitable adhesive for mounting LGA package 211 to substrate 202. Then the pads of the LGA package 211 are wire bonded to the 3D package substrate 202.

Rather than mounting a second package onto the LGA package 211, the die 204 is die bonded directly to the package substrate 212 of the LGA package 211, on a side opposite the LGA package die 214. For this purpose, the surface of the LGA package substrate 212 onto which the die 204 is mounted should only have lands 213 around its periphery, so that the die 204 does not lie on top of any of the lands 213 of substrate 212. An adhesive such as an epoxy, for example, Ablestick Ablebond 8355F epoxy may be used for die bonding.

The pads (not shown) of the die 204 are then wire bonded by wires 206 to the package substrate 202 of the 3D package. The die 204 can be flip-chip mounted to the LGA substrate 212 in other embodiments of the invention, as shown and described further below, with reference to FIG. 3. Then a second layer of encapsulant or molding compound 230 is applied, to encapsulate the LGA package 211, die 204, and wires 206 and 222. A single mass of an encapsulant 230 encapsulates the LGA package 211 and the second die 204. An exemplary molding compound for this purpose is Plaskon SMT-B-1 Series.

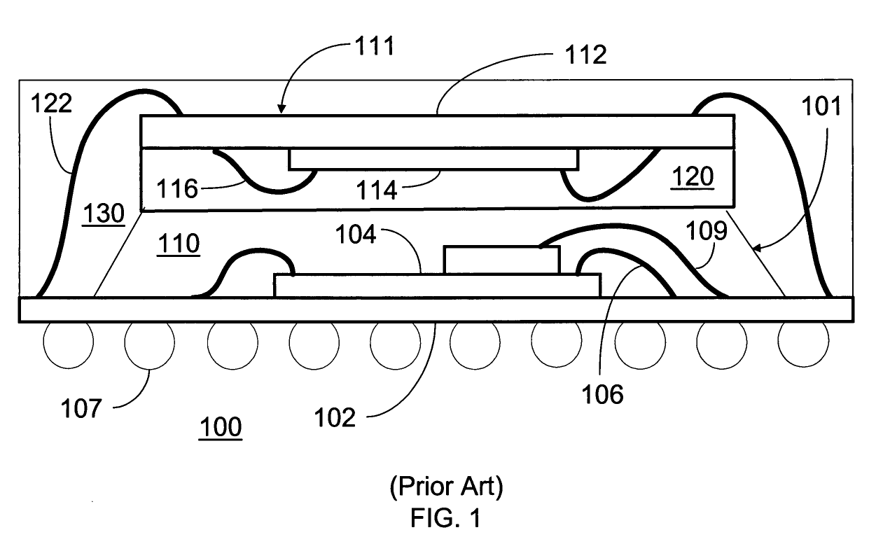

The above described method only requires two separate molding processes, for molding compounds 220 and 230. This decreases the cost and fabrication time of the 3D package 200 relative to the package 100 of FIG. 1. Further the thickness of the 3D package 200 is can be thinner than the package 100 of FIG. 1, because only two layers of encapsulant 220 and 230, respectively cover the die 204, wires 206, 222, and the package and 211. Essentially, the thickness of a separate molding compound layer 110 between the die 104 and the LGA package 111 is eliminated from the embodiment of FIG. 2.

FIG. 3 is a diagram of another embodiment of a 3D package 300, in which die 305 is flip-chip mounted to the LGA substrate 312 by solder balls 315. Other elements of FIG. 3, which are the same as those described above with reference to FIG. 2, are indicated by like reference numerals increased by 100. These include digital die 304, wires 306 for bonding the digital die 304, solder balls 307, bonding wires 309 for the analog die, LGA package substrate 312, lands 313, wires 316 for wire bonding the die 314 within the LGA package 311, overmold 320, wires 322 for bonding the LGA package to the substrate 302, and overmold 330. Descriptions of these items are not repeated.

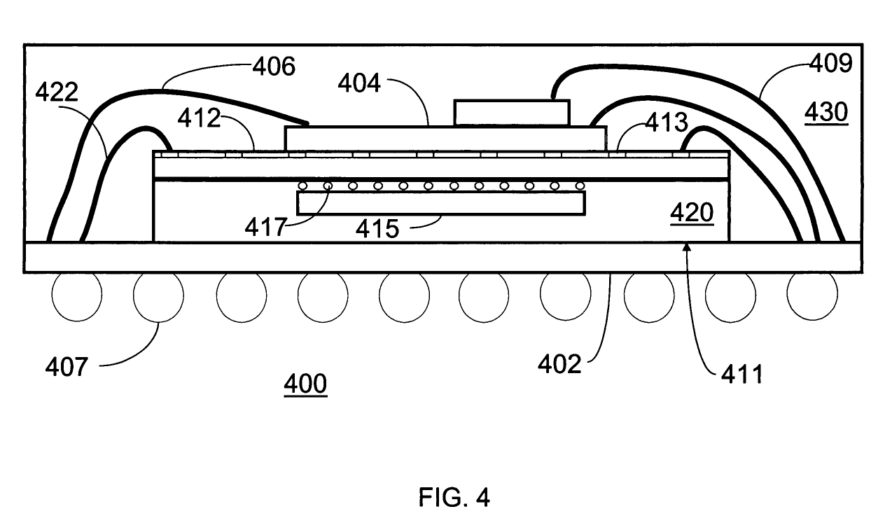

FIG. 4 is a diagram of another embodiment of a 3D package 400, in which the LGA package 411 includes a die 415 that is flip-chip mounted to the substrate 402, using solder balls 417. Other elements of FIG. 4, which are the same as those described above with reference to FIG. 2, are indicated by like reference numerals increased by 200. These include digital die 404, wires 406 for bonding the digital die 404, solder balls 407, bonding wires 409 for the analog die, LGA package substrate 412, lands 413, overmold 420, wires 422 for bonding the LGA package to the substrate 402, and overmold 430. Descriptions of these items are not repeated.

Although examples are described above in which an LGA package is incorporated into a 3D package, other types of packages may be incorporated into a 3D package using the techniques described above. For example, the techniques described above with reference to FIGS. 2-4 may be applied in configurations where the package 211, 311 or 411 is a quad flat no-lead (QFN) package.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A packaging method, comprising the steps of:
mounting on a three-dimensional (3D) package substrate a land grid array (LGA) or quad flat no-lead (QFN) package having an LGA or QFN die on a first side of an LGA or QFN package substrate, respectively; and
mounting a second die directly on a second side of the LGA or QFN package substrate opposite the first side thereof.

2. The method of claim 1, further comprising wire bonding a plurality of lands of the LGA or QFN package to contacts on the 3D package substrate.

3. The method of claim 2, further comprising wire bonding a plurality of contacts of the second die to contacts on the 3D package substrate.

4. The method of claim 3, further comprising encapsulating the LGA or QFN package and the second die in a single encapsulation step.

5. The method of claim 4, further comprising applying a plurality of solder balls to pads on a side of the 3D package substrate opposite the LGA or QFN package, thereby to form the 3D package.

6. The method of claim 1, further comprising encapsulating the LGA or QFN package and the second die in a single encapsulation step.

7. The method of claim 1, further comprising orienting the LGA or QFN package with the LGA or QFN package substrate facing away from the 3D package substrate.

8. The method of claim 1, wherein the LGA or QFN package comprises a flip-chip mounted die.

9. A 3D package, comprising:
a three-dimensional (3D) package substrate;
a land grid array (LGA) or quad flat no-lead (QFN) package mounted on the 3D package substrate, the LGA or QFN package having an LGA or QFN die on a first side of an LGA or QFN package substrate; and
a second die mounted directly on a second side of the LGA or QFN package substrate opposite the first side thereof.

10. The 3D package of claim 9, wherein the LGA or QFN package has a plurality of lands wire bonded to contacts on the 3D package substrate.

11. The 3D package of claim 10, wherein the second die has a plurality of contacts wire bonded to contacts on the 3D package substrate.

12. The 3D package of claim 11, further comprising an encapsulant encapsulating the LGA or QFN package and the second die.

13. The 3D package of claim 12, further comprising a plurality of solder balls connected to pads on a side of the 3D package substrate opposite the LGA or QFN package.

14. The 3D package of claim 9, further comprising a single mass of an encapsulant, encapsulating the LGA or QFN package and the second die.

15. The 3D package of claim 9, wherein the LGA or QFN package is oriented with the LGA or QFN package substrate facing away from the 3D package substrate.

16. A 3D package, comprising:
a three-dimensional (3D) package substrate;
a land grid array (LGA) or quad flat no-lead (QFN) package mounted on the 3D package substrate, the LGA or QFN package having an LGA or QFN die on a first side of an LGA or QFN package substrate, the LGA or QFN package having a plurality of lands wire bonded to contacts on the 3D package substrate, the LGA or QFN package being oriented with the LGA or QFN package substrate facing away from the 3D package substrate;
a second die mounted on a second side of the LGA or QFN package substrate opposite the first side thereof, the second die having a plurality of contacts wire bonded to contacts on the 3D package substrate;
a single mass of a molding compound, encapsulating the LGA or QFN package and the second die; and
a plurality of solder balls connected to pads on a side of the 3D package substrate opposite the LGA or QFN package.
